(19) United States
(12) Patent Application Publication
(10) Pub. No.: US 2022/0064787 A1
(43) Pub. Date: Mar. 3, 2022

(54) METHOD FOR SURFACE TREATMENT OF QUARTZ COMPONENT

(71) Applicant: CHANGXIN MEMORY TECHNOLOGIES, INC., Hefei City (CN)

(72) Inventor: Jiazhou Yuan, Hefei (CN)

(73) Assignee: CHANGXIN MEMORY TECHNOLOGIES, INC., Hefei City (CN)

(21) Appl. No.: 17/445,084

(22) Filed: Aug. 14, 2021

Related U.S. Application Data
(63) Continuation of application No. PCT/CN2021/096923, filed on May 28, 2021.

(30) Foreign Application Priority Data
Aug. 28, 2020 (CN) 202010883169.1

(51) Int. Cl. C23C 16/44; G01B 21/30; B24C 1/00; B01J 19/10

(52) U.S. Cl. CPC C23C 16/4404; C23C 16/4407; B01J 19/10; B24C 1/00; G01B 21/30

(57) ABSTRACT

A surface treatment method for quartz component includes: sandblasting the quartz component; ultrasonically treating the sandblasted quartz component to remove a sharp corner formed on the surface of the quartz component; immersion cleaning the quartz component; and drying the cleaned quartz component.

### CROSS-REFERENCE TO RELATED APPLICATIONS

The present application is a continuation of International Application No. PCT/CN2021/096923 filed on May 28, 2021, which claims priority to Chinese Patent Application No. 202010883169.1 filed on Aug. 28, 2020. The disclosures of these applications are hereby incorporated by reference in their entirety.

### BACKGROUND

According to an existing semiconductor manufacturing device such as a TEL HP-Ti reaction chamber of a TF CVD machine table, titanium films may be continuously accumulated in the reaction chamber due to manufacturing processes, so that films accumulated on the surface of a quartz component on which a wafer is placed in the machine table are growing thicker and thicker. During manufacturing of a wafer, the films accumulated on the surface of the quartz component easily fall on the surface of the wafer, leading to an abnormal growth of a film on the surface of the wafer. At present, the problem of bad surface adhesive force of the quartz component cannot be prevented in advance, and can only be found when the electrical property of a wafer in a test machine and a back station is abnormal.

### SUMMARY

The present disclosure relates generally to the technical field of semiconductors, and more specifically to a surface treatment method for a quartz component.

The embodiments of the present disclosure provide a surface treatment method for a quartz component, which may include operations of: sandblasting the quartz component; ultrasonically treating the sandblasted quartz component to remove a sharp corner formed on a surface of the quartz component; immersion cleaning the quartz component; and drying the cleaned quartz component.

### BRIEF DESCRIPTION OF THE DRAWINGS

In order to more clearly explain the technical solutions of the embodiments of the present disclosure, the accompanying drawings used in the embodiments will be briefly introduced below. The drawings herein are incorporated in and constitute a part of this specification, and serve to explain the technical solutions of the embodiments of the present disclosure together with the description. It is to be understood that the following drawings illustrate only certain examples of the present disclosure and are therefore not to be considered limiting of its scope. For those of ordinary skill in the art, other related drawings may be obtained from the drawings without involving any inventive effort.

FIG. 1 is flowchart I of a surface treatment method for a quartz component according to an example of the present disclosure.

FIG. 2 is flowchart II of a surface treatment method for a quartz component according to an example of the present disclosure.

FIG. 3 is a schematic structure diagram of a sandblasted quartz component with films attached.

FIG. 4 illustrates an image acquisition picture of the surface of a sandblasted quartz component.

FIG. 5 is a schematic diagram of a surface structure of an ultrasonically treated quartz component.

FIG. 6 illustrates an image acquisition picture of the surface of an ultrasonically treated quartz component.

Reference Numerals:

1: a quartz component; 2: a sandblasting layer formed on the surface of a sandblasted quartz component; 3: a sharp corner; and 4: a linear film.

### DETAILED DESCRIPTION

In order to make the objects, technical solutions, and advantages of the embodiments of the present disclosure clearer, the technical solutions in the examples of the present disclosure will be clearly and completely described below with reference to the drawings in the examples of the present disclosure. It is apparent that the described examples are only a part of the examples of the present disclosure, not all of the examples. Therefore, the following detailed description of the examples of the present disclosure provided in the accompanying drawings is not intended to limit the scope of the claimed embodiments of the present disclosure, but is merely representative of selected examples of the present disclosure. All other examples obtained by those skilled in the art based on the examples of the present disclosure without creative efforts should fall within the scope of protection of the embodiments of the present disclosure.

A surface treatment method for a quartz component as set forth in the present disclosure is described in further detail below with reference to the drawings and detailed description.

The surface treatment method for the quartz component according to an example of the present disclosure is described below with reference to the accompanying drawings. An execution body of the examples of the present disclosure may be a surface treatment device.

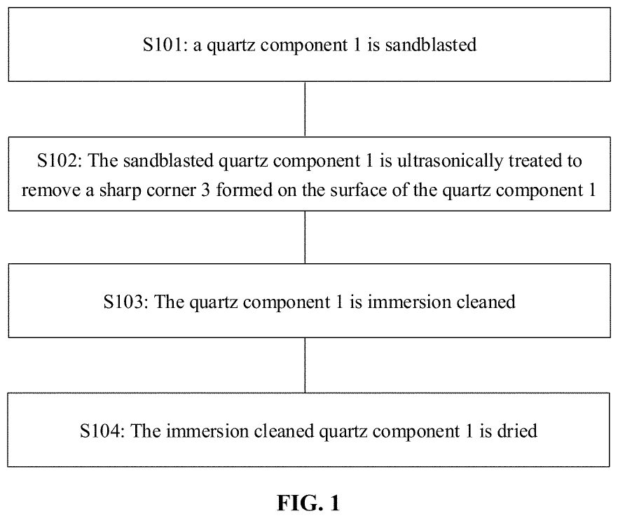

As shown in FIG. 1, the surface treatment method for the quartz component according to an example of the present disclosure includes the following operations.

In S101, a quartz component 1 is sandblasted.

In S102, the sandblasted quartz component 1 is ultrasonically treated to remove a sharp corner 3 formed on the surface of the quartz component 1.

In S103, the quartz component 1 is immersion cleaned.

In S104, the immersion cleaned quartz component 1 is dried.

The above operations are illustrated below, respectively.

In S101, in a semiconductor manufacturing device, the quartz component 1 may be located in a deposition chamber, e.g., around a plasma spray head for collecting plasma gas to the upper side of a chamber bearing platform. In the process of depositing on a wafer or manufacturing a wafer, a film with a certain thickness is inevitably attached and formed on the surface of the quartz component 1. The adhesive force of the film on the surface of the quartz component 1 is low, thus the film easily falls on the surface of a wafer resulting in an abnormal wafer. Roughness of the surface of the quartz component 1 may be enhanced by sandblasting the surface of the quartz component 1 to form a sandblasted layer 2, so that the adhesive force of the film on the surface of the quartz component 1 can be greatly increased, thereby preventing the film from falling on the surface of a wafer which otherwise may cause an abnormal yield of manufacturing a wafer.

It is to be noted that the sandblasting process is a process of cleaning and roughening the surface of a substrate by the impact of a high-speed sand flow. Compressed air provides power to form a high-speed spray beam to spray materials (copper ore, quartz sand, carborundum, iron sand, and Hainan sand) onto a surface of a workpiece to be treated at a high speed, so that the appearance or shape of an outer surface of the workpiece is changed. Due to the impact and cutting action of abrasives on the workpiece surface, the workpiece surface obtains certain cleanness and different roughness, and the mechanical property of the workpiece surface is improved. Therefore, the fatigue resistance of the workpiece is improved, the adhesive force between the workpiece and a film thereon is increased, and the durability of the film is prolonged.

It is to be noted that when the surface treatment device sandblasts the quartz component 1, quartz sand may be used for sandblasting, so that the surface roughness of the quartz component 1 can be increased, the adhesive force of a film can be enhanced, and the film will not easily fall off. When sandblasting, the surface treatment device may sandblast an inner wall surface where a wafer is accommodated on and a partial outer wall surface of the quartz component 1. The partial quartz component 1 may be shielded by a shielding component only exposing the part of the quartz component 1 to be sandblasted, thus waste of sandblasting materials is reduced. In other examples of the present disclosure, quartz sand may also be used for sandblasting.

In some examples of the present disclosure, the surface treatment device may use 180-mesh small-particle quartz sand for fixed-angle sandblasting in the sand blasting process so as to improve the uniformity of the surface roughness of the sandblasted quartz component. In the present example, the sandblasting may be performed at an angle of 70-90 degrees to the quartz surface, such as 70 degrees, 75 degrees, 80 degrees, 85 degrees, or 90 degrees. The sandblasting pressure is 3-5 kg force, which may be 3 kg, 3.5 kg, 4 kg, 4.5 kg, or 5 kg. The distance between a jet head of a sandblasting machine and the surface of the quartz component 1 to be sandblasted is 8-10 cm, such as 8 cm, 9 cm, or 10 cm, so that the sandblasting can be more uniform, and requirements of the roughness of the quartz component meeting can be achieved.

In S102, after the surface treatment device sandblasts the surface of the quartz component 1, some sharp corners 3 may be formed on the surface of the quartz component 1. In the subsequent wafer film growth process, a film growing at the sharp corner 3 of the quartz component 1 hangs down linearly to form a linear film 4. The linear film 4 easily falls off on to wafer. In order to reduce the abnormal yield caused by the falling of the linear film 4 on the surface of a wafer, the surface treatment device may ultrasonically oscillate the sandblasted quartz component 1 to remove the sharp corner 3 formed on the surface of the quartz component 1, so that the surface roughness of the quartz component 1 is more uniform, and a linear film 4 is prevented from growing at the sharp corner 3 in subsequent processes, thus the yield of the wafer is further improved.

The roughness Ra2 of the ultrasonically treated quartz component 1 and the roughness Ra1 of the sandblasted quartz component 1 satisfy: 95% Ra1≤Ra2≤105% Ra1. Therefore, an error between the roughness of the ultrasonically treated quartz component 1 and the roughness of the sandblasted quartz component 1 is ±5%, whereby the adhesion of the surface of the quartz component 1 to a film can be ensured, and the defect of a product caused by the sharp corner 3 formed after the sandblasting can be avoided with the roughness within the above range. It is to be noted that when the quartz component is ultrasonically treated and cleaned cyclically for several times, the roughness Ra2 of the ultrasonically treated quartz component 1 refers to the roughness of the quartz component 1 after being ultrasonically treated for the several times.

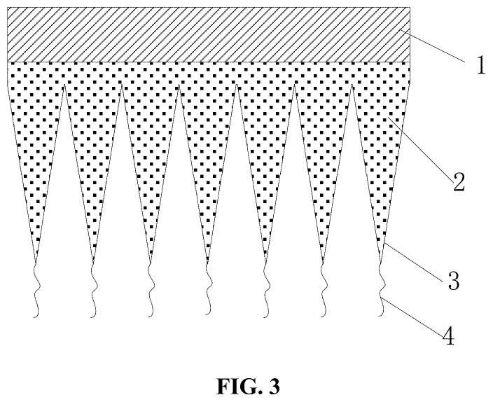

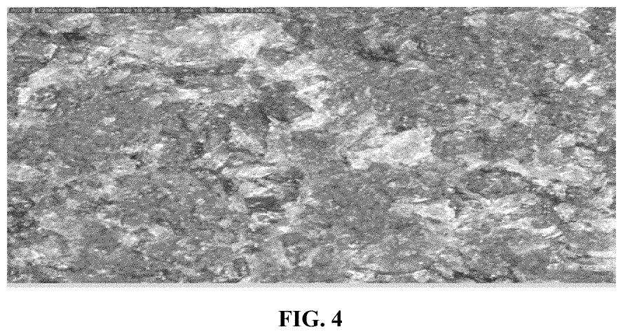

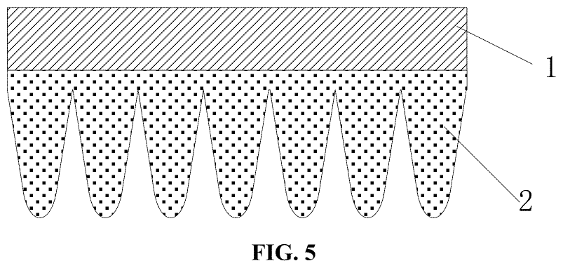

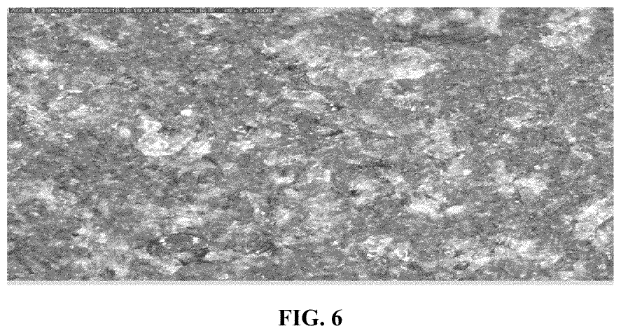

FIG. 3 is a schematic structure diagram of a sandblasted quartz component 1 after a film being attached. FIG. 4 illustrates an image acquisition picture of the surface of a sandblasted quartz component 1. As shown in FIGS. 3 and 4, the surface of the sandblasted quartz component 1 has apparently acute angles and sharp protruding points, and the linear films 4 are attached to the sharp corners 3 formed after sandblasting. FIG. 5 is a schematic diagram of a surface structure of an ultrasonically treated quartz component 1. FIG. 6 illustrates an image acquisition picture of the surface of an ultrasonically treated quartz component 1. As shown in FIG. 6, the surface of the quartz component 1 has a relatively flat angle and no particularly protruding point. As shown in FIG. 5, the surface of the ultrasonically treated quartz component 1 has no sharp corner 3, thus no linear film 4 can be attached.

In S103, after being ultrasonically treated, particles falling due to the oscillation are on the surface of the quartz component 1, and the particles falling on the surface of the quartz component 1 may be washed away by immersion cleaning the quartz component 1 with the surface treatment device. The quartz component 1 may be ultrasonically treated and immersion cleaned for several times. That is to say, the surface treatment device may ultrasonically treat and clean the quartz component 1 for two or more times. Specifically, after the quartz component 1 is ultrasonically treated once, the quartz component 1 is immersion cleaned once to wash away particles on the surface of the quartz component 1, and then the quartz component 1 is ultrasonically treated and immersion cleaned. The operation is cyclically performed for many times to remove the sharp corner 3 on the surface of the quartz component 1.

In S104, after being ultrasonically treated and cleaned by the surface treatment device for many times, the quartz component 1 may be dried.

In some examples of the present disclosure, when the quartz component 1 is ultrasonically treated, the frequency of ultrasonic oscillation may be 100-150 KHZ or 120-140 KHZ. The power of ultrasonic oscillation may be 130-170 HZ or 145-160 HZ. The ultrasonic treatment may be performed for a time period of 10-20 min or 13-18 min. The quartz component 1 may be immersion cleaned with ultra-pure water for 15-25 min.

In some examples of the present disclosure, the surface treatment device may ultrasonically oscillate the quartz component 1 at a frequency of 130 KHZ and a power of 155 HZ for 15 min. After the sharp corner 3 is removed, the quartz component is washed with ultra-pure water for 20 min, where the ultra-pure water may be at an ambient temperature. The sharp corner formed on the surface of the sandblasted quartz component may be removed by the ultrasonic treatment under such conditions, the difference between the surface roughness of the ultrasonically treated quartz component and that of the sandblasted quartz component may be maintained within a range of +/−5%, so that the surface roughness of the quartz component is maintained when removing the sharp corner. The adhesive force of the film on the surface of the quartz component is improved, and abnormal wafer yield caused by falling films on the surface of a wafer is avoided.

It is to be noted that the time for the ultrasonic treatment herein refers to the total time of ultrasonic treatment used in the surface treatment method for the quartz component 1 in the examples of the present disclosure. For example, when the ultrasonic treatment and immersion cleaning processes are carried out only once, the quartz component 1 is ultrasonically treated once for 10-20 min or 13-18 min, and then cleaned for 15-25 min. As another example, the ultrasonic treatment and the immersion cleaning may be carried out for several times. Then, the total time of ultrasonically treating the quartz component 1 for the several times is 10-20 min or 13-18 min, and the time of immersion cleaning for the several times is 15-25 min. The ultrasonic treatment and the immersion cleaning may be carried out repeatedly for 3-4 times. The ultrasonic treatment may be carried out for 3-5 min each time, and the immersion cleaning may be carried out for 4-7 min each time.

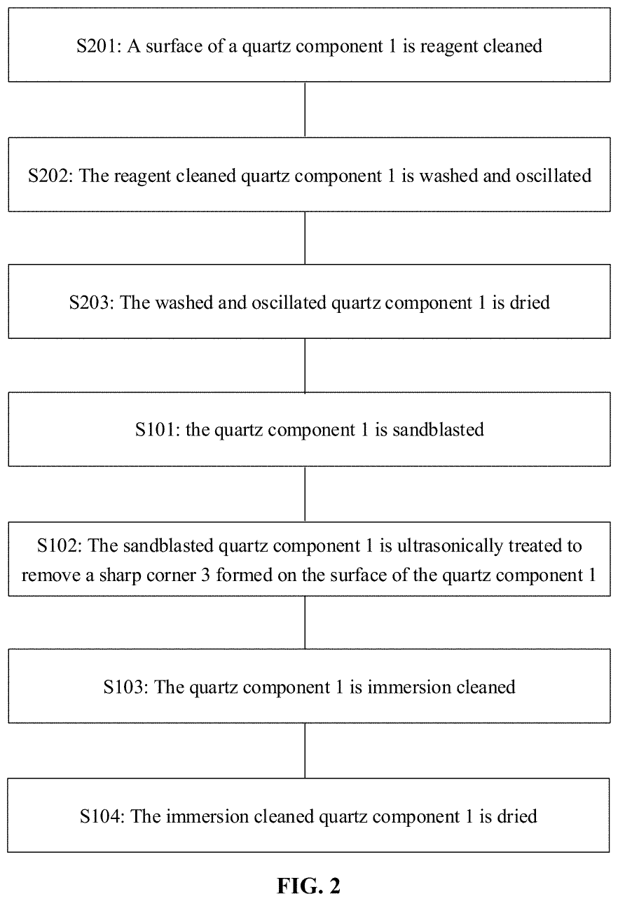

In some examples of the present disclosure, as shown in FIG. 2, before S101, the method further includes the following operations.

In S201, reagent cleaning is performed on a surface of the quartz component 1.

In S202, the reagent cleaned quartz component 1 is washed and oscillated.

In S203, the washed and oscillated quartz component 1 is dried.

Therefore, before the quartz component 1 is sandblasted, the film formed on the surface of the quartz component 1 can be effectively removed, and the surface roughness of the quartz component 1 can be more uniform, so that uniform sandblasting on the quartz component 1 is facilitated, therefore, the surface roughness of the sandblasted quartz component 1 is more uniform and consistent, and the generation of the sharp corner 3 and the linear film 4 at the sharp corner 3 is reduced.

In some examples of the present disclosure, the film deposited on the surface of the quartz component 1 is titanium. When the quartz component 1 is subjected to reagent cleaning, the reagent may be a mixed solution of hydrogen peroxide and potassium hydroxide. The concentration of the hydrogen peroxide may be 40% and the concentration of the potassium hydroxide may be 20%, thereby effectively removing the film formed on the quartz surface. It is to be noted that the composition of the reagent solution at the time of reagent cleaning is not limited thereto, and different reagent cleaning may be selected according to different materials of films.

In some examples of the present disclosure, after the cleaned quartz component 1 is dried, the method further includes the following operation. The surface roughness of the quartz component 1 is detected to judge whether the surface roughness of the quartz component 1 meets a preset roughness standard. If the surface roughness of the quartz component 1 is not uniform, the thickness and resistance value distribution of the film formed on the surface of the quartz component 1 may shift when a film grows in a subsequent process. The thickness of the film deposited on the surface of the quartz component is not uniform since the surface roughness of the quartz component is not uniform during the subsequent film deposition process. Therefore, the concentration of plasma gas in each region in the chamber is affected to be not uniform. Finally, the thickness of a film deposited on a wafer is inconsistent. The uniformity of the surface roughness of the quartz component 1 can be judged by detecting the surface roughness of the quartz component 1. When the surface roughness of the quartz component 1 does not meet the preset roughness standard, the quartz component 1 may be further treated, so that the surface roughness of the quartz component 1 is more uniform and meets the preset roughness standard.

In the examples of the present disclosure, the operation of detecting the surface roughness of the quartz component 1 may include the following operations. A plurality of detection points of the quartz component 1 are selected. Specifically, a plurality of detection points of an inner sidewall of the quartz component 1 and a plurality of detection points of an outer sidewall of the quartz component 1 may be selected for detection. The plurality of detection points are measured to obtain respective roughness. When determining whether the surface roughness of the quartz component 1 meets a preset roughness standard, it is judged whether the roughness meets the preset roughness standard. When the roughness of the detection points does not meet the preset roughness standard, a detection point region with high roughness is polished and a detection point region with low roughness is sandblasted until the roughness of the plurality of detection points meets the preset roughness standard.

For example, a region with a high roughness value may be polished with a scouring pad to reduce the roughness, and a region with a low roughness value may be sandblasted again to increase the roughness, so that the surface roughness of the treated quartz component 1 is more uniform, the adhesion of a film is facilitated, and the generation of the linear film 4 is reduced.

The preset roughness standard is that the roughness of each detection point is 4.5-7.5 μm and a maximum difference in the roughness of the plurality of detection points is less than 2 μm. Therefore, the roughness of the plurality of detection points on the surface of the quartz component 1 may be controlled to be 4.5-7.5 μm, and the difference between a maximum roughness value and a minimum roughness among the detection points need to be controlled within 2 μm, so that the surface roughness of the treated quartz component 1 is more uniform.

In some examples of the present disclosure, eight detection points of the inner side wall of the quartz component 1 and eight detection points of the outer side wall of the quartz component 1 may be selected for detection. The inner side wall is the closest part of the quartz component 1 to a plasma gas jet head. The following table shows roughness values of 16 detection points of a quartz component 1 before sandblasting, after sandblasting, and after ultrasonic treatment. And in the sandblasting process, 180-mesh small-particle quartz sand is used for 90-degree fixed-angle sandblasting, the frequency of ultrasonic treatment is 130 KHZ, the power is 155 HZ, and the oscillation time is 15 min.

Table 1 is roughness values respectively measured before sandblasting, after sandblasting, and after ultrasonic treatment at detection points No. 1-8 of a quartz component.

TABLE 1
Detection point

| | 1 | 2 | 3 | 4 | 5 | 6 | 7 | 8 |
|---|---|---|---|---|---|---|---|---|
| Before | 0.95 | 1.07 | 0.99 | 1.00 | 1.03 | 0.96 | 1.01 | 0.97 |
| sandblasting | | | | | | | | |
| After | 5.33 | 5.74 | 5.36 | 4.79 | 5.47 | 5.55 | 4.96 | 5.36 |
| sandblasting | | | | | | | | |
| After ultrasonic | 5.33 | 5.75 | 5.25 | 4.79 | 5.47 | 5.51 | 4.97 | 5.38 |
| treatment | | | | | | | | |

Table 2 is roughness values respectively measured before sandblasting, after sandblasting, and after ultrasonic treatment at detection points No. 9-16 of a quartz component.

TABLE 2
Detection point

| | 9 | 10 | 11 | 12 | 13 | 14 | 15 | 16 |
|---|---|---|---|---|---|---|---|---|
| Before | 1.05 | 1.22 | 1.16 | 1.26 | 1.21 | 1.29 | 1.33 | 1.29 |
| sandblasting | | | | | | | | |
| After | 4.16 | 5.49 | 4.72 | 5.75 | 5.77 | 4.69 | 5.76 | 5.25 |
| sandblasting | | | | | | | | |
| After ultrasonic | 4.16 | 5.55 | 4.75 | 5.79 | 5.72 | 4.75 | 5.76 | 5.25 |
| treatment | | | | | | | | |

The table comparison shows that the roughness of the quartz component 1 is greatly enhanced after sandblasting, the sharp corner 3 formed on the surface of the quartz component 1 can be reduced after the sandblasted quartz component 1 is ultrasonically treated, and the difference between the surface roughness of the ultrasonically treated quartz component and that of the sandblasted quartz component may be maintained within a range of +/−5%, so that the surface roughness of the quartz component is maintained when removing the sharp corner, the adhesive force of the film on the surface of the quartz component is improved, and the generation of the linear film 4 is avoided, which further reducing the risk that the film on the surface of the quartz component 1 falls onto the surface of a wafer.

The above descriptions are merely some implementations of the present disclosure, it is to be noted that some modifications and alterations may be conceived by those of ordinary skill in the art without departing from the principle of the present disclosure, and such modifications and alterations are also considered to be within the scope of protection of the present disclosure.

Examples of the present disclosure provide a surface treatment method for a quartz component, which includes operations of: sandblasting the quartz component; ultrasonically treating the sandblasted quartz component to remove a sharp corner formed on the surface of the quartz component; immersion cleaning the quartz component; and drying the cleaned quartz component. Through the above method, the surface roughness of the quartz component can be increased, the adhesive force of the quartz component can be enhanced, and the sharp corner formed by sandblasting the quartz component can be removed, so that a linear film is prevented from being formed on the surface of the quartz component in the manufacturing process, and the yield of a wafer is improved.

What is claimed is:

1. A method for surface treatment of a quartz component, comprising:
sandblasting the quartz component;
ultrasonically treating the sandblasted quartz component to remove a sharp corner formed on a surface of the quartz component;
immersion cleaning the quartz component; and
drying the immersion cleaned quartz component.

2. The method for surface treatment of a quartz component according to claim 1, further comprising, prior to said sandblasting the quartz component:
reagent cleaning the quartz component;
washing and oscillating the reagent cleaned quartz component; and
drying the washed and treated quartz component.

3. The method for surface treatment of a quartz component according to claim 1, wherein in a step of ultrasonically treating the sandblasted quartz component to remove the sharp corner formed on the surface of the quartz component, a roughness Ra2 of the ultrasonically treated quartz component and a roughness Ra1 of the sandblasted quartz component satisfy: 95% Ra1≤Ra2≤105% Ra1.

4. The method for surface treatment of a quartz component according to claim 3, wherein in a step of ultrasonically treating the sandblasted quartz component, a frequency of ultrasonic treatment is 100-150 KHZ.

5. The surface treatment method for the quartz component according to claim 3, wherein in a step of ultrasonically treating the sandblasted quartz component, the ultrasonically treating is performed for a time period of 10-20 min.

6. The method for surface treatment of a quartz component according to claim 1, further comprising, after said drying the immersion cleaned quartz component:
detecting surface roughness of the quartz component to judge whether the surface roughness of the quartz component meets a preset roughness standard.

7. The method for surface treatment of a quartz component according to claim 6, wherein a step of detecting the surface roughness of the quartz component comprises following steps:
selecting two or more detection points of the quartz component;
measuring the detection points to obtain respective roughness; and
when determining whether the surface roughness of the quartz component meets the preset roughness standard, determining whether the respective roughness meets the preset roughness standard.

8. The method for surface treatment of a quartz component according to claim 7, wherein the preset roughness standard is that the respective roughness of each of the detection points is 4.5-7.5 μm and a maximum difference of the roughness among the detection points is less than 2 μm.

9. The method for surface treatment of a quartz component according to claim 7, further comprising, after said determining whether the plurality of roughness meets the preset roughness standard:
responding to the roughness of the detection points does not meet the preset roughness standard, polishing a region with a detection point having high roughness and sandblasting a region with a detection point having low roughness until the roughness of the detection points meets the preset roughness standard.

10. The method for surface treatment of a quartz component according to claim 1, wherein in the steps of ultrasonically treating the sandblasted quartz component and immersion cleaning the quartz component, repeating the steps of ultrasonically treating the sandblasted quartz component and immersion cleaning the quartz component for two or more times.
